(19) United States
(12) Patent Application Publication
(10) Pub. No.: US 2012/0008406 A1
(43) Pub. Date: Jan. 12, 2012

(54) NONVOLATILE MEMORY DEVICE AND METHOD OF OPERATING THE SAME

(76) Inventor: Jin Haeng LEE, Seoul (KR)

(21) Appl. No.: 13/166,194

(22) Filed: Jun. 22, 2011

(30) Foreign Application Priority Data
Jul. 9, 2010 (KR) 10-2010-0066489

(51) Int. Cl. G11C 16/10; G11C 16/04

(52) U.S. Cl. 365/185.19; 365/185.22; 365/185.18

(57) ABSTRACT

A method of operating a nonvolatile memory device includes programming first memory cells to make threshold voltages of the first memory cells to reach a verification voltage determined based on program data of second memory cells to be programmed, and programming the second memory cells.

### CROSS-REFERENCE TO RELATED APPLICATION

Priority to Korean patent application number 10-2010-0066489 filed on Jul. 9, 2010, the entire disclosure of which is incorporated by reference herein, is claimed.

### BACKGROUND

Exemplary embodiments relate to a nonvolatile memory device and a method of operating the same and, more particularly, to a program method of a nonvolatile memory device.

A nonvolatile memory device includes a memory cell array for storing data. The memory cell array includes a plurality of cell blocks. Each of the cell blocks includes cell strings each including a plurality of cells. Each of the cell strings is coupled with a page buffer through a bit line. When a program operation is performed, voltage levels of the bit lines are determined based on program data inputted to the page buffers. The memory cells are classified into memory cells to be programmed and memory cells not to be programmed and programmed based on the voltage levels of the corresponding bit lines.

Meanwhile, with an increase in the degree of integration of nonvolatile memory devices, when a program operation is performed, interference may occur between neighboring memory cells and change their threshold voltages.

FIG. 1 is a diagram illustrating the distribution of threshold voltages according to a conventional program operation.

Referring to FIG. 1, in multi-level cells (MLCs) programmable in various levels, threshold voltages of the multi-level cells may be classified into an erase state ER and various program states 10 according to levels of the threshold voltages.

A program operation may be performed by dividing memory cells into even memory cells and odd memory cells. A cell group selected from among the even memory cells and the odd memory cell is first programmed, and the remaining cell group is then programmed. For example, in the case where the even memory cells are first programmed, program data corresponding to the even memory cells is inputted to relevant page buffers, and the even memory cells are programmed based on the inputted program data. At this time, since program data corresponding to the odd memory cells has not been inputted to relevant page buffers yet, whether the odd memory cells have been programmed cannot be known while the even memory cells are programmed. When all the threshold voltages of the programmed even memory cells reach program target levels PV1, PV2, and PV3 (10), the program operation for the even memory cells is terminated, and a program operation for the odd memory cells is performed.

In order to program the odd memory cells, the program data corresponding to the odd memory cells is inputted to the relevant page buffers. That is, when the even memory cells are programmed, only the program data corresponding to the even memory cells is inputted to the page buffers. When the odd memory cells are programmed, only the program data corresponding to the odd memory cells is inputted to the page buffers. When the odd memory cells are programmed based on the inputted program data, the threshold voltages of the even memory cells already programmed may rise because of interference (12).

As described above, if the threshold voltages of the even memory cells which have already been programmed to rise over the final target levels, erroneous data may be read from the even memory cells in a read operation. Consequently, reliability of the nonvolatile memory device may be degraded.

### BRIEF SUMMARY

According to exemplary embodiments of this disclosure, program data corresponding to both even memory cells and odd memory cells are inputted to relevant page buffers and program target levels of the even memory cells may be controlled based on the program data corresponding to the odd memory cells when the even memory cells are programmed based on the program data corresponding to the even memory cells.

A method of operating a nonvolatile memory device according to an aspect of the present disclosure includes programming first memory cells to make threshold voltages of the first memory cells to reach a verification voltage determined based on program data of second memory cells to be programmed, and programming the second memory cells.

A method of operating a nonvolatile memory device according to another aspect of the present disclosure includes inputting program data of even and odd pages to respective page buffers, setting a program target level of the odd page based on the program data of the even page, performing a program operation for the odd page to make threshold voltages of the memory cells of the odd page to reach the set program target level, and performing a program operation for the even page.

A nonvolatile memory device according to an aspect of the present disclosure includes a memory cell array including first memory cells and second memory cells, a voltage generator configured to generate operation voltages for programming, reading, or erasing the first memory cells and the second memory cells to global lines, a row decoder configured to supply the operation voltages to the memory cell array through local lines, page buffers configured to precharge or discharge bit lines, coupled to the memory cell array, in response to first and second program data to be stored in the first and second memory cells, respectively, at a program operation, a data check circuit configured to output data signals based on the second program data stored in the page buffers, and a control circuit configured to determine a verification voltage of the first memory cells in response to the data signals and control the voltage generator based on a result of the determination.

### BRIEF DESCRIPTION OF THE DRAWINGS

FIG. 1 is a diagram illustrating the distribution of threshold voltages according to a conventional program operation;

FIG. 2 is a block diagram of a nonvolatile memory device according to an exemplary embodiment of this disclosure;

FIG. 3 is a flowchart illustrating a program method according to an exemplary embodiment of this disclosure;

FIG. 4 is a block diagram of a page buffer of the nonvolatile memory device according to an exemplary embodiment of this disclosure; and

FIG. 5 is a diagram illustrating the distribution of threshold voltages according to a program operation of this disclosure.

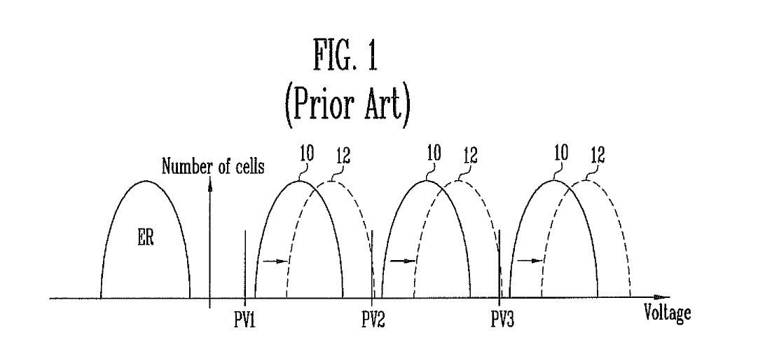

### DESCRIPTION OF EMBODIMENTS

Hereinafter, some exemplary embodiments of the present disclosure will be described in detail with reference to the accompanying drawings. The figures are provided to enable those of ordinary skill in the art to make and use the embodiments of the disclosure.

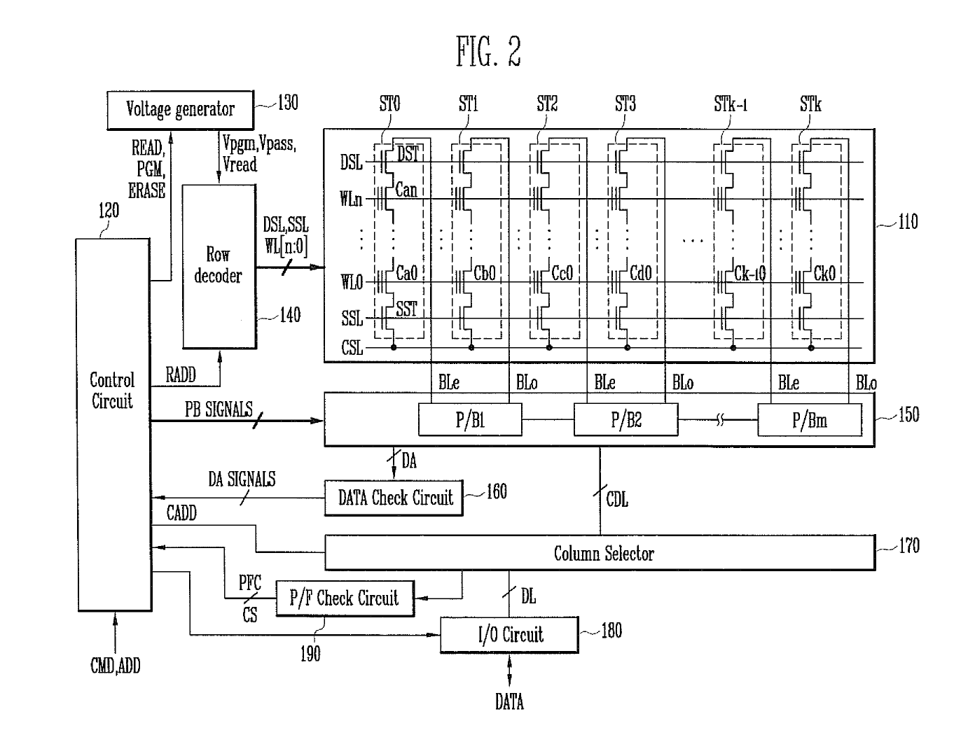

FIG. 2 is a block diagram of a nonvolatile memory device according to an exemplary embodiment of this disclosure.

The nonvolatile memory device according to the exemplary embodiment of this disclosure includes a memory cell array 110, an operation circuit group (130, 140, 150, 160, 170, 180, and 190), and a control circuit 120 for controlling the operation circuit group. The operation circuit group performs a program operation or a read operation for the even memory cells and the odd memory cells of the memory cell array 110. The program operation may be performed by inputting program data for the even memory cells and the odd memory cells at the same time and lowering threshold voltages of cells to be first programmed based on the inputted program data. In a NAND flash memory device, the operation circuit group may include a voltage generator 130, a row decoder 140, a page buffer circuit 150, a data check circuit 160, a column selector 170, an I/O circuit 180, and a P/F check circuit 190.

The memory cell array 110 may include a plurality of memory blocks. Only one of the memory blocks is shown in FIG. 2, for convenience. The memory block includes a plurality of strings ST0 to STk. Each of the strings, for example, ST0, includes a source select transistor SST coupled to a common source line CSL, a plurality of memory cells Ca0 to Can, and a drain select transistor DST coupled with a bit line BLe. The memory cells Ca0 to Can are classified into even memory cells and odd memory cells according to the arranged order. For example, cells included in even-numbered strings ST0, ST2, ST4, . . . may be called even memory cells, and cells included in odd-numbered strings ST1, ST3, ST5, . . . may be called odd memory cells. The gates of the source select transistors SST of the strings are coupled to a source select line SSL, the gates of the memory cells thereof are coupled to respective word lines WL0 to WLn, and the gates of the drain select transistors DST thereof are coupled to a drain select line DSL. The strings ST1 to STk are coupled to a corresponding bit line BLe or BLo and to the common source line CSL. The bit lines coupled to the even-numbered strings ST0, ST2, ST4, . . . are called even bit lines BLe, and the bit lines coupled to the odd-numbered strings ST1, ST3, ST5, . . . are called odd bit lines BLo.

The control circuit 120 internally generates a program operation signal PGM, a read operation signal READ, or an erase operation signal ERASE in response to a command signal CMD and generates control signals PB SIGNALS for controlling the page buffers of the page buffer circuit 150 based on the type of an operation. Furthermore, the control circuit 120 internally generates a row address signal RADD and a column address signal CADD in response to an address signal ADD. Furthermore, the control circuit 120 checks whether the threshold voltages of selected memory cells have increased to at least a target voltage level in response to a check signal PFC generated by a P/F check circuit 190 during a program verification operation and determines whether to perform or terminate a program operation based on a result of the check.

A voltage supply circuit (130 and 140) supplies operation voltages for a program operation, an erase operation, or a read operation of memory cells to the drain select line DSL, the word lines WL0 to WLn, and the source select line SSL of a selected memory block in response to the signals READ, PGM, ERASE, and RADD of the control circuit 120. The voltage supply circuit includes a voltage generator 130 and a row decoder 140.

The voltage generator 130 outputs operation voltages for programming, reading, or erasing memory cells to the global lines in response to the operation signals PGM, READ, and ERASE of the control circuit 120 (that is, the internal command signals). For example, the voltage generator 130 outputs operation voltages Vpgm, Vpass, and Vread to the global lines.

The row decoder 140 transfers the operation voltages of the voltage generator 130 to the strings ST1 to STk of a memory block, selected from among the memory blocks of the memory cell array 110, in response to the row address signal RADD of the control circuit 120. That is, the operation voltages are supplied to the local lines DSL, WL[0:n], and SSL of the selected memory block.

The page buffer circuit 150 includes page buffers P/B1 to P/Bm each coupled to the bit lines BLe and BLo. The even bit line BLe and the odd bit line BLo coupled to each page buffer form a pair. That is, the even and odd bit lines BLe and BLo are coupled to one page buffer. The page buffer circuit 150 further includes a plurality of latches (not shown). Program data is stored in the latches, or data read from cells is stored in the latches. The page buffer circuit 150 supplies voltages for storing data in the cells Ca0 to Ck0 to the respective bit lines BLe and BLo in response to the control signals PB SIGNALS of the control circuit 120. More particularly, when a program operation, an erase operation, or a read operation for the memory cells Ca0 to Ck0 is performed, the page buffer circuit 150 precharges the bit lines BLe and BLo or latches data corresponding to threshold voltages of the memory cells Ca0 to Ck0 detected based on voltages of the bit lines BLe and BLo. That is, the page buffer circuit 150 controls voltages of the bit lines BLe and BLo based on data stored in the memory cells Ca0 to Ck0 and detects data stored in the memory cells Ca0 to Ck0.

The data check circuit 160 receives odd program data signals DA from the respective page buffers P/B1 to P/Bm, checks whether the odd program data is data to be programmed, and outputs data signals DA SIGNALS to the control circuit 120. The control circuit 120 determines a program target level of a program operation in response to the data signals DA SIGNALS.

The column selector 170 selects the page buffers of the page buffer circuit 150 in response to the column address signal CADD of the control circuit 120. In a read operation, data latched in page buffers selected by the column selector 170 is outputted.

During a program operation, the I/O circuit 180 transfers externally inputted program data to the column selector 170 through a data line DL under the control of the control circuit 120 in order to input the program data to the page buffer circuit 150. For example, in the embodiment of this disclosure, since program data include all data corresponding to the even memory cells and the odd memory cells, the program data of 8 KB (kilobyte) may be inputted to the I/O circuit 180. Accordingly, the column selector 170 sequentially transfers the program data of 8 KB to the page buffers P/B1 to P/Bm of the page buffer circuit 150 through a column data line CDL. Accordingly, all the program data of the even memory cells and the program data of the odd memory cells are inputted to each of the page buffers. Furthermore, in a read operation, the I/O circuit 180 externally outputs data received from the page buffers P/B1 to P/Bm via the column selector 170.

The P/F check circuit 190 checks whether an error cell having a threshold voltage lower than a target voltage exists in programmed memory cells in a program verification operation performed after a program operation and outputs a result of the check as a check signal PFC. Furthermore, the P/F check circuit 190 also counts the number of generated error cells and outputs a result of the count as a count signal CS.

A method of programming even memory cells and odd memory cells by changing a program target level based on program data in the nonvolatile memory device described above is described as follows.

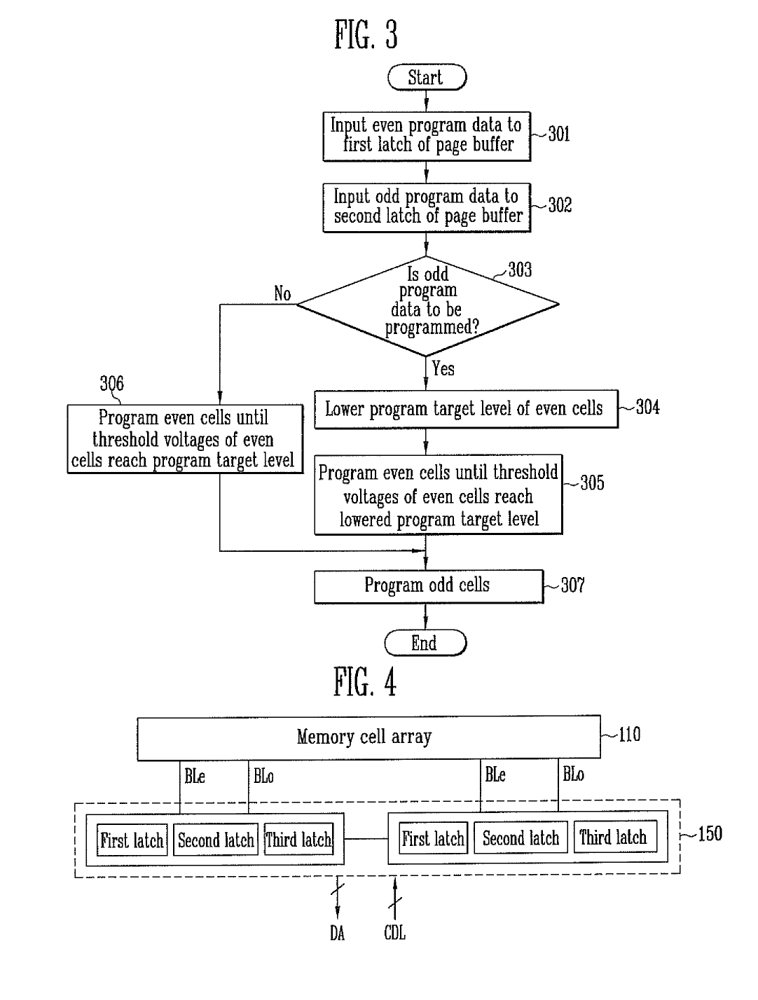

FIG. 3 is a flowchart illustrating a program method according to an exemplary embodiment of this disclosure.

At a program operation, cells selected from among the even memory cells and the odd memory cells are first programmed, and the remaining cells are programmed. In the embodiment of this disclosure, the even memory cells may be first programmed and then the odd memory cells may be programmed.

Referring to FIG. 3, when a program operation starts, program data is inputted to the latches of a page buffer at steps 301 and 302. One or more latches are included in one page buffer. In the embodiment of this disclosure, three or more latches may be used. If one page buffer includes a first latch to a third latch, even program data for even memory cells are inputted to the first latch at step 301 and odd program data for odd memory cells are inputted to the second latch at step 302. The third latch may be used when a program or verification operation is performed.

It is checked at step 303 whether the odd program data of the program data inputted to the page buffer is target program data to be programmed. If, as a result of the check, the odd program data is the target program data (that is, data for program target cells), a program target level of the even memory cells is set to be lowered at step 304 out of consideration for interference which will be generated when a program operation for the odd memory cells is subsequently performed. The program target level may be lowered sufficiently enough to compensate for an increment of threshold voltages of the even memory cells which is caused by interference due to the program operation for the odd memory.

The even memory cells are programmed until all the threshold voltages of the even memory cells reach the set program target level at step 305. The program operation for the even memory cells may be performed using an incremental step pulse program (ISPP) method of gradually raising a program voltage. First, the even bit lines BLe are precharged or discharged based on the even program data inputted to the page buffer. Next, the even memory cells are programmed by supplying the program voltage to a selected word line. It is verified whether the threshold voltages of the even memory cells have reached the set program target level. The program and verification operations are repeatedly performed until all the threshold voltages of the even memory cells reach the set program target level.

After the program operation for the even memory cells is performed, the odd memory cells are programmed using the odd program data inputted to the page buffer at step 307. In the program operation of the even memory cells, the program target level is lowered according to whether the odd memory cells are programmed. However, the program operation of the odd memory cells is performed without changing the program target level because a subsequent program operation does not exist. The program operation of the odd memory cells may be performed using the same incremental step pulse program (ISPP) method as the program operation of the even memory cells.

If, as a result of the check at step 303, the odd program data is not the target program data (that is, data for program target cells), the even memory cells are programmed without lowering the program target level of the even memory cells at step 306. After the even memory cells are programmed, the odd memory cells are programmed at step 307.

After the program operation for the odd memory cells is completed, the program operation is terminated.

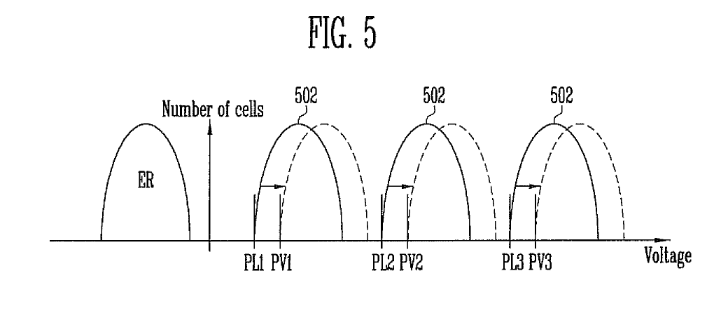

The step 303 of checking whether the odd program data is data to be programmed is described with reference to FIG. 4.

FIG. 4 illustrates a block diagram of a page buffer for explaining the program method according to an exemplary embodiment of this disclosure.

Referring to FIG. 4, the memory cell array 110 and the page buffer circuit 150 are coupled through the even and odd bit lines BLe and BLo. The page buffer circuit 150 includes the plurality of page buffers. Each of the page buffers may include the first to third latches. Program data for the even memory cells and the odd memory cells is inputted through the column data line CDL. Even program data is inputted to the first latch, and odd program data is inputted to the second latch.

A method of performing the data check step 303 according to a first embodiment is described as follows.

The odd program data inputted to the second latches of the respective page buffers is sequentially outputted to the data check circuit 160. The outputted data may be referred to as the odd program data signals DA. The data check circuit 160 determines whether the odd program data is data to be programmed based on the odd program data signals DA. The data check circuit 160 sequentially outputs the data signals DA SIGNALS (that is, results of the determination) to the control circuit 120. The control circuit 120 sets the program target level to be used for the program operation of the even memory cells in response to the data signals DA SIGNALS. If both the odd memory cells neighboring on both sides of the even memory cell are to be programmed or any one of the neighboring odd memory cells is to be programmed, the program target level of the even memory cell may be set to be lowered. The program target level is set out of consideration for a shift in threshold voltages of the even memory cells, which is caused by interference due to a program operation for the odd memory cells.

A method of performing the data check step according to a second embodiment is described as follows.

Since data has not yet been inputted to the third latches of the page buffers, respectively, data inputted to the second latches of the page buffers are transferred to the third latches. More particularly, the data inputted to the second latch of the first page buffer is transferred to the third latch of the first page buffer. The data inputted to the second latch of the second page buffer is transferred to the third latch of the first page buffer and to the third latch of the second page buffer, respectively. The data check circuit 160 receives the data stored in the third latches of the page buffers, checks whether the odd memory cells neighboring on both sides of the even memory cells are to be programmed, and sends the data signals DA SIGNALS (that is, results of the checks) to the control circuit 120.

According to the above program operation, the threshold voltages of the even memory cells may be set as follows.

FIG. 5 is a diagram illustrating the distribution of threshold voltages of the even memory cells according to the program operation of this disclosure.

Referring to FIG. 5, the even memory cells maintain an erase state ER or the even memory cells are programmed in various levels, based on even program data inputted to relevant page buffers. Here, if the odd memory cells neighboring the even memory cells to be programmed are also to be programmed, the even memory cells are programmed to have threshold voltages of a first reference level PL1, a second reference level PL2, and a third reference level PL3 which are lower than a first program target level PV1, a second program target level PV2, and a third program target level PV3 (that is, final program target levels), respectively. For example, when the first program target level PV1 is 2.1 V, the first reference level PL1 may be set to be 1.9 V, which is lower than the first program target level PV1 by 0.2 V. Here, the first reference level PL1 is set to be lower than the first program target level PV1 by a shift in threshold voltages of the even memory cells which results from interference due to a program operation of the odd memory cells. Likewise, the second reference level PL2 and the third reference level PL3 are set.

Accordingly, the threshold voltages of the even memory cells may have a level lower than the final program target level before the odd memory cells are programmed (502). However, when the odd memory cells are programmed, the threshold voltages of the even memory cells are increased owing to the occurring interference and reach the final program target level.

According to the present disclosure, cells to be first programmed are programmed to have threshold voltages lower than a program target level. Accordingly, even though the threshold voltages of the first programmed cells are increased owing to the interference of a program operation for cells to be subsequently programmed, such an increment can be compensated for. Accordingly, reliability of a program operation and a subsequent read operation can be increased.

What is claimed is:

1. A method of operating a nonvolatile memory device, the method comprising:
programming first memory cells to make threshold voltages of the first memory cells to reach a verification voltage determined based on program data of second memory cells to be programmed; and
programming the second memory cells.

2. The method of claim 1, further comprising inputting program data of the first and second memory cells to page buffers of the first memory cells and the second memory cells to be programmed, respectively, before the programming of the first memory cells.

3. The method of claim 2, wherein:
if the second memory cells are to be programmed, the verification voltage of the first memory cells is determined to be lowered, and
if the second memory cells are not to be programmed, the verification voltage of the first memory cells is determined to be maintained.

4. The method of claim 3, wherein the verification voltage of the first memory cells is determined to be lowered by a shift in threshold voltage of the first memory cells occurring when the second memory cells are programmed.

5. The method of claim 1, wherein the programming of the first and second memory cells are performed using an incremental step pulse program (ISPP) method.

6. A method of operating a nonvolatile memory device, the method comprising:
inputting program data of even and odd pages to respective page buffers;
setting a program target level of the odd page based on the program data of the even page;
performing a program operation for the odd page to make threshold voltages of memory cells of the odd page to reach the set program target level; and
performing a program operation for the even page.

7. The method of claim 6, wherein the program operations for the odd and even pages are performed using an incremental step pulse program (ISPP) method.

8. A nonvolatile memory device, comprising:
a memory cell array comprising first memory cells and second memory cells;
a voltage generator configured to generate operation voltages for programming, reading, or erasing the first memory cells and the second memory cells to global lines;
a row decoder configured to supply the operation voltages to the memory cell array through local lines;
page buffers configured to precharge or discharge bit lines, coupled to the memory cell array, in response to first and second program data to be stored in the first and second memory cells, respectively, at a program operation;
a data check circuit configured to output data signals based on the second program data stored in the page buffers; and
a control circuit configured to determine a verification voltage of the first memory cells in response to the data signals and control the voltage generator based on a result of the determination.

9. The nonvolatile memory device of claim 8, wherein each of the page buffers comprises a plurality of latches for storing the first and second program data.

10. The nonvolatile memory device of claim 9, wherein each of the page buffers comprises a first latch for storing the first program data and a second latch for storing the second program data among the latches.

11. The nonvolatile memory device of claim 10, wherein each of the page buffers further comprises a third latch for receiving data from the second latches of other page buffers among the latches.

12. The method of claim 8, wherein the first memory cells neighbor on the second memory cells, respectively:
if the second memory cells are to be programmed, the verification voltage of the first memory cell is determined to be lowered; and
if the second memory cells are not to be programmed, the verification voltage of the first memory cell is determined to be maintained.
